(19) United States
(12) Patent Application Publication
(10) Pub. No.: US 2011/0006926 A1
(43) Pub. Date: Jan. 13, 2011

(54) TRAINING APPARATUS AND METHOD BASED ON MOTION CONTENT

(75) Inventors: Sung-Eun Kim, Seoul (KR); Sung-Weon Kang, Daejeon (KR); Tae-Wook Kang, Daejeon (KR); Nak-Woong Eum, Daejeon (KR); Kyung-Soo Kim, Daejeon (KR); Jung-Bun Kim, Daejeon (KR); Jin-kyung Kim, Daejeon (KR); Hyung-Il Park, Daejeon (KR); In-Gi Lim, Daejeon (KR); Chang-Hee Hyoung, Daejeon (KR); Jung-Hwan Hwang, Daejeon (KR); Hey-Jin Myoung, Seoul (KR); Ki-Hyuk Park, Daejeon (KR); Jae-Hoon Shim, Daejeon (KR)

Correspondence Address: AMPACC Law Group, PLLC, 6100 219th Street SW, Suite 580, Mountlake Terrace, WA, 98043, US

(73) Assignee: Electronics and Telecommunications Research Institute, Daejeon (KR)

(21) Appl. No.: 12/922,751

(22) PCT Filed: Jan. 19, 2009
(86) PCT No.: PCT/KR2009/000280

§ 371 Date: Sep. 15, 2010

(30) Foreign Application Priority Data
Apr. 3, 2008 (KR) 10-2008-0031348
Sep. 12, 2008 (KR) 10-2008-0090488

(51) Int. Cl. H03K 17/94

(52) U.S. Cl. 341/20

(57) ABSTRACT

A training apparatus based on motion content includes a plurality of motion detecting sensors (11 a . . . 11 n) dispersedly arranged in a body of a user to obtain position information signals of respective body parts of the user, a motion controller (20) analyzing the position information signals to detect a user motion, and comparing the detected motion with a reference motion provided from motion contents to generate a motion calibration signal for training of a motion calibration, and a plurality of motion calibrating sensors (12a . . . 12n) dispersedly arranged in the body to stimulate the body part of the user according to the motion calibration signal and calibrate the user motion, and consequently can provide a training service for continual motions and increase a motion calibration effect.

### TECHNICAL FIELD

The present invention relates to a training apparatus based on motion content, and more particularly, to a training apparatus based on motion content, which includes motion contents having predefined motions to be taught and enables a user to learn the motion contents.

### BACKGROUND ART

In general, the conventional motion control method disposes a position sensor and a position calibration sensor in specific positions, and gives power or vibration to a corresponding body part when any body part of a user is disposed in a corresponding position.

The conventional motion control method senses the occurrence of a wrong motion or pose and informs the sensed wrong motion or pose, but cannot suggest about that a user must take any activity and pose in any order for learning motions which are continued according to a specific subject.

Consequently, it is impossible to provide a training service that enables users to learn motion contents having motions which is continued according to specific subjects such as education, health care and leisure sports using the conventional motion control method.

Moreover, there is another motion control method that gives a sensuous restriction to a user on the use of an equipment by mounting a feeling sensor onto the equipment used by the user. However, although another motion control method gives a sensuous restriction to user motions, it cannot suggest a right motion direction to users.

### DISCLOSURE OF INVENTION

### Technical Problem

An aspect of the present invention provides a training apparatus and method based on motion content, which can provide a training service to users using motion contents having predefined reference motions to be taught to users.

Another aspect of the present invention provides a training apparatus and method based on motion content, which can more easily accurately train motions according to motion contents to users.

### Technical Solution

According to an aspect of the present invention, there is provided a training apparatus based on motion content, including: a plurality of motion detecting sensors dispersedly arranged in a body of a user to obtain position information signals of respective body parts of the user; a motion controller analyzing the position information signals to detect a user motion, and comparing the detected motion with a reference motion provided from motion contents to generate a motion calibration signal for training of a motion calibration; and a plurality of motion calibrating sensors dispersedly arranged in the body to stimulate the body part of the user according to the motion calibration signal and calibrate the user motion.

The motion controller may include: a signal interface interfacing a signal transceived between the motion detecting sensors, the motion calibrating sensors and the motion controller; a current motion analyzer analyzing the position information signal obtained through the motion detecting sensor to detect the user motion; a motion comparator comparing the user motion with the reference motion provided from the motion contents; a motion error calculator calculating a motion error which is a difference between the user motion and the reference motion; and a motion calibration signal generator generating the motion calibration signal for training a motion calibration based on the motion error.

The motion controller may further include a motion content storage storing the motion contents.

The motion calibration signal may include information of a body part where the motion error occurs, an error direction and an error degree.

The motion calibrating sensor may vary a stimulation direction and stimulation degree of the body part of the user according to the motion calibration signal.

According to another aspect of the present invention, there is provided a training method based on motion content, including: obtaining a position value by body part of a user to sense a user motion; comparing a reference motion provided from motion contents with the user motion to calculate a motion error; and stimulating a feeling of the body part of the user where the motion error occurs to train a motion calibration.

The sensing of the user motion may include: obtaining the position value by body part of the user through a plurality of motion detecting sensors which are dispersedly arranged in the body of the user; and analyzing the position value by body part of the user to detect the user motion.

The calculating of the motion error may include comparing the reference motion provided from the motion contents with the user motion to detect a body part where the motion error occurs, an error direction and an error degree.

The stimulating of the feeling may include varying a stimulation direction and stimulation degree of a body part where the motion error occurs through a plurality of motion calibrating sensors which are dispersedly arranged in the body of the user.

### ADVANTAGEOUS EFFECTS

The training apparatus and method based on motion content according to an embodiment of the present invention control a user motion according to motion contents having predefined reference motions to be taught to users, thereby suggesting about that users must take any activity and pose in any order for learning continual motions. That is, embodiments of the present invention can provide a training service for motions having specific subjects such as education, health care and leisure sports.

Moreover, embodiments of the present enables users to more accurately receive and control their motion by dispersedly arranging at least one sensor onto bodies of the users or worn items, thereby maximizing a training effect for the users.

### BRIEF DESCRIPTION OF DRAWINGS

The above and other aspects, features and other advantages of the present invention will be more clearly understood from the following detailed description taken in conjunction with the accompanying drawings, in which:

FIG. 1 is a block diagram of a training apparatus based on motion content according to an embodiment of the present invention;

FIG. 2 is a flowchart for describing a training method based on motion content according to an embodiment of the present invention;

FIG. 3 is a flowchart for describing a training method based on motion content according to another embodiment of the present invention;

FIG. 4 is an exemplary diagram illustrating the use of the training apparatus based on motion content according to an embodiment of the present invention; and

FIG. 5 is an exemplary diagram illustrating another use of the training apparatus based on motion content according to an embodiment of the present invention.

### BEST MODE FOR CARRYING OUT THE INVENTION

Exemplary embodiments of the present invention capable of being easily embodied by those skilled in the art will now be described in detail with reference to the accompanying drawings. In the following description, when the detail description of the relevant known function or configuration is determined to unnecessarily obscure the important point of the present invention, the detail description will be omitted.

In the accompanying drawings, a portion irrelevant to a description of the present invention will be omitted for clarity. Like reference numerals refer to like elements throughout.

Additionally, it will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof unless otherwise defined.

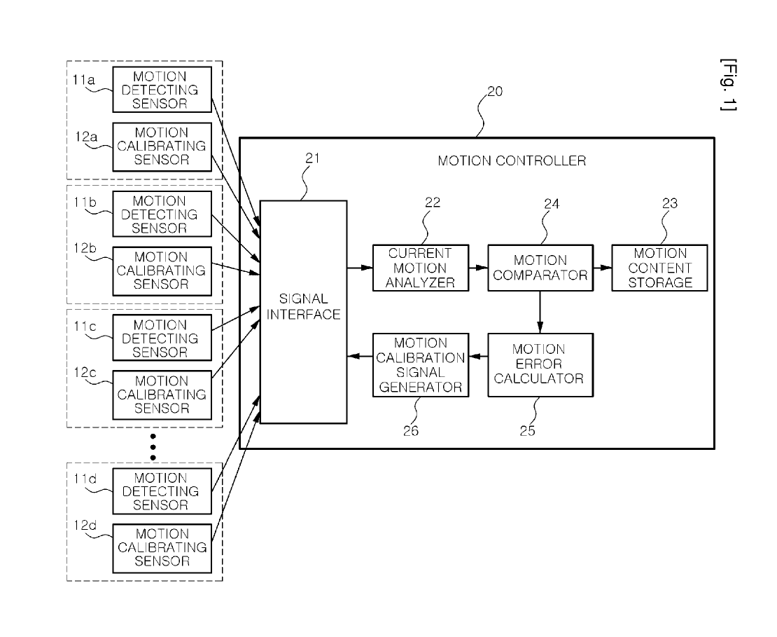

FIG. 1 is a block diagram of a training apparatus based on motion content according to an embodiment of the present invention.

Referring to FIG. 1, the training apparatus based on motion content includes a plurality of motion detecting sensors 11a to 11n, a plurality of motion calibrating sensor 12a to 12n, and a motion controller 20.

The respective motion detecting sensors 11a to 11n may be implemented with all sorts of position sensors capable of obtaining a Three-Dimensional (3D) position value. The respective motion calibrating sensors 12a to 12n may be implemented with a haptic sensor capable of varying a feeling stimulation direction and a feeling stimulation degree or a device capable of performing the same function as the varying function.

Moreover, the motion controller 20 may include at least one device, which can process signals and store information, such as a Digital Signal Processor (DSP), a micro controller, a Field Programmable Gate Array (FPGA) and the like.

Hereinafter, functions of the respective elements of the training apparatus will be described below.

The motion detecting sensors 11a to 11n are dispersedly arranged onto the body of a user or worn items of the user (for example, clothing). The motion detecting sensors 11a to 11n obtain position values by body part of the user which is varied according to a user motion (i.e., activity and pose), generates position information signals for the notification of the obtained values, and provide the generated signals to the motion controller 20.

Like the motion detecting sensors 11a to 11n, the motion calibrating sensors 12a to 12n are dispersedly arranged onto the body of the user or the worn items. The motion calibrating sensors 12a to 12n vary a stimulation direction and a stimulation degree for the body of the user requiring a motion calibration in response to a motion calibration signal provided from the motion controller 20, and thus inform the user of which part of the body requires the motion calibration and in which direction and by how much the body part must be moved.

At this point, the motion calibration signal is a signal provided by the motion controller 20, and includes information of a body part in which a motion error occurs, an error direction and an error degree.

The motion controller 20 compares a reference motion provided from motion contents to be taught to the user with a user motion to thereby check whether a motion error occurs. When the motion error occurs, the motion controller 20 trains a right motion to the user so that the user can take the right motion.

For this, the motion controller 20 includes a signal interface 21, a current motion analyzer 22, a motion content storage 23, a motion comparator 24, a motion error calculator 25, and a motion calibration signal generator 26.

The signal interface 21 is connected to the motion detecting sensors 11a to 11n and the motion calibrating sensors 12a to 12n, and interfaces a signal transmitted between the motion detecting sensors 11a to 11n, the motion calibrating sensors 12a to 12n and the motion controller 20.

That is, the signal interface 21 demodulates the position information signal transmitted from the motion detecting sensors 11a to 11n to change the transmitted signal into a signal recognizable with the current motion analyzer 22. Alternatively, the signal interface 21 modulates the motion calibration signal transmitted from the motion calibration signal generator 26 to thereby change the transmitted signal into a signal capable of being transmitted to the motion calibrating sensors 12a to 12n, and thereafter outputs the changed signal to the outside.

At this point, the signal interface 21 uses a signal modulation/demodulation scheme according to a well-known technology, and may use any one of a wired communication scheme, a wireless communication scheme and a humanoid communication scheme. A signal, which is transmitted between the motion detecting sensors 11a to 11n, the motion calibrating sensors 12a to 12n and the signal interface 21, is an electric signal such as an analog signal or a digital signal.

The current motion analyzer 22 has the predefined correlation between position values by body part and motions. When the position information signal is transmitted from the motion detecting sensors 11a to 11n, the current motion analyzer 22 obtains the position values by body part and thereafter detects a current motion of the user on the basis of the predefined correlation.

The motion content storage 23 stores motion contents having predefined reference motions to be taught to the user. At this point, the motion contents may include continual motions having subjects associated with education, health care, leisure sports and the like. Examples of the motions may include dance composition, martial arts and the like.

The motion comparator 24 compares a current motion of the user obtained through the current motion analyzer 22 with a reference motion of the motion contents corresponding to the obtained motion to thereby detect a difference between the reference motion and the obtained motion.

The motion error calculator 25 analyzes the difference obtained through the motion comparator 24 to calculate a motion error. At this point, the motion error has information of the body part in which a motion error occurs, the error direction and the error degree.

The motion calibration signal generator 26 generates the motion calibration signal for training a right motion to the user on the basis of the motion error detected by the motion error calculator 25, and provides the generated motion calibration signal to the motion calibrating sensors 12a to 12n.

Subsequently, the motion calibrating sensors 12a to 12n vary a stimulation direction and a stimulation degree for the bodyguard in which the motion error occurs in response to the motion calibration signal, and thus enables the user to recognize in which part of the body the motion error occurs and in which direction and by how much the body part must be moved.

In an embodiment of the present invention illustrated in FIG. 1, the motion detecting sensors 11a to 11n are separated from the motion calibrating sensors 12a to 12n, but the motion detecting sensors 11a to 11n and the motion calibrating sensors 12a to 12n may be integrated with one sensor when necessary.

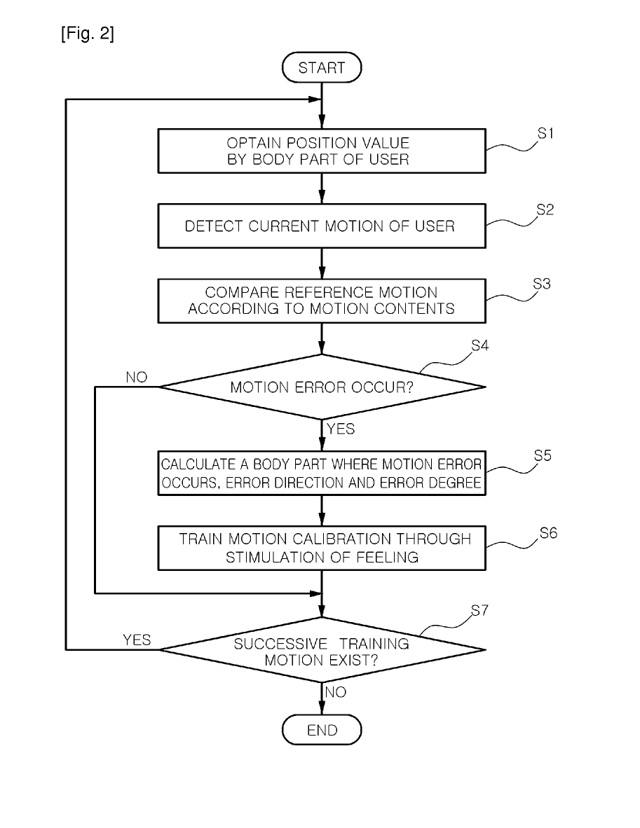

FIG. 2 is a flowchart for describing a training method based on motion content according to an embodiment of the present invention.

First, when training based on motion content starts, the motion controller 20 obtains the position values by body part of the user through the motion detecting sensors 11a to 11n in operation S1.

The motion controller 20 analyzes the obtained position values by body part to detect a current motion of the user in operation S2, and thereafter compares the current motion of the user with a reference motion provided from the motion contents in operation S3.

When the comparison result of the operation S3 shows that the current motion of the user is different from the reference motion provided from the motion contents and a motion error occurs in operation S4, the motion controller 20 calculates the body part in which the motion error occurs, the error direction and the error degree in operation S5.

Then, the motion controller 20 generates the motion calibration signal including information calculated through the operation S5 and provides the generated signal to the motion calibrating sensors 12a to 12n, and the motion calibrating sensors 12a to 12n train calibration for the body part in which the motion error occurs in response to the motion calibration signal in operation S6.

That is, the motion calibrating sensors 12a to 12n vary a stimulation direction and a stimulation degree for the body part in which the motion error occurs in response to the motion calibration signal, and thus inform the user of which part of the body requires the motion calibration and in which direction and by how much the body part must be moved.

When the operation S6 is completed, the motion controller 20 checks whether there is a successive training motion on the basis of the motion contents in operation S7. When the check result shows that there is the successive training motion, the training method again returns to the operation S1. On the other hand, when the check result shows that there is no successive training motion, the training method based on motion content is completed.

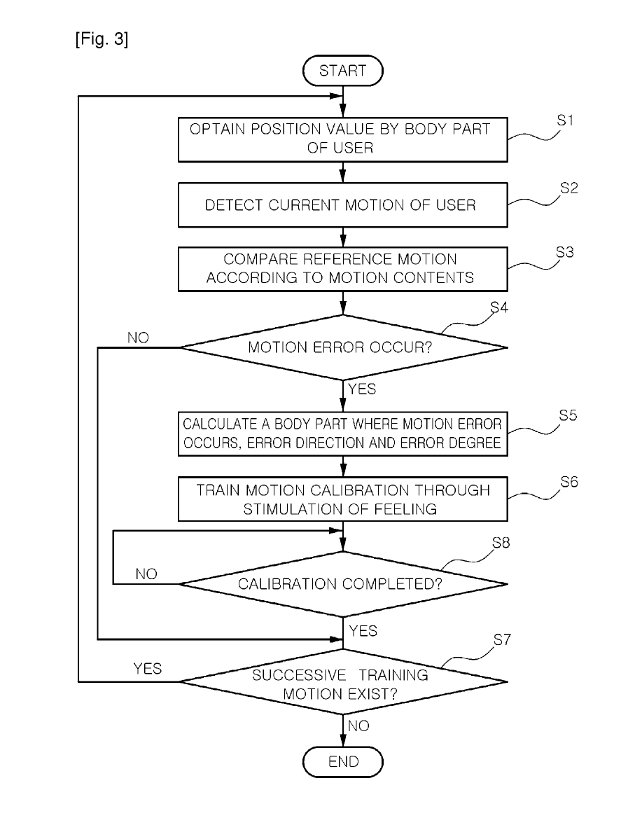

Moreover, the training method based on motion content according to an embodiment of the present invention may add an operation S8 of checking the completion of calibration between the operations S6 and S7 for further increasing a training effect as illustrated in FIG. 3.

That is, the motion calibrating sensors 12a to 12n train calibration for the body part in which the motion error occurs in the operation S6. Subsequently, only in a case where the user calibrates its motion to take the reference motion provided from the motion contents in operation S8, the training method can proceed to a succeeding operation.

In this case, only in a case where the training apparatus identifies that the user's motion is accurately calibrated, the user can learn a succeeding motion. Accordingly, an embodiment of the present invention can provide an accurate motion calibration effect to the user.

As described above, the training apparatus and method based on motion content according to an embodiment of the present invention repeatedly perform a motion sensing process and a motion calibrating process, and thus can suggest about that the user must take any activity and pose in any order for learning motions which are continued according to a specific subject.

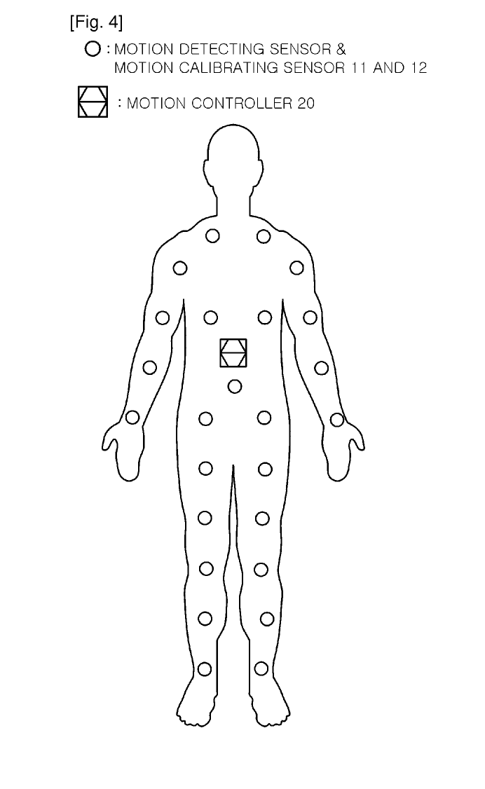

FIG. 4 is an exemplary diagram illustrating the use of the training apparatus based on motion content according to an embodiment of the present invention.

Referring to FIG. 4, the motion detecting sensors 11a to 11n and the motion calibrating sensors 12a to 12n are dispersedly arranged onto the body of the user or the worn items of the user (for example, clothing), and the motion controller 20 is disposed in a specific body part of the user or the outside of the body part.

The motion detecting sensors 11a to 11n, the motion calibrating sensors 12a to 12n and the motion controller 20 communicate with one another in any one of the wired communication scheme, the wireless communication scheme and the human body communication scheme as described above.

When the motion controller 20 communicates with the motion detecting sensors 11a to 11n, the motion calibrating sensors 12a to 12n in the human body communication scheme, the motion controller 20 must necessarily be in contact with or adjacent to a specific body part of the user. This reason is for enabling the motion detecting sensors 11a to 11n, the motion calibrating sensors 12a to 12n and the motion controller 20 to transceive a signal using the human body as a transmission medium.

In this way, the motion detecting sensors 11a to 11n are dispersedly arranged onto the body of the user, and thus can more accurately sense and inform position values by body part according to a user motion. Accordingly, the motion controller 20 can more accurately detect the current motion of the user based on the sensed position values.

With the same principle, the motion calibrating sensors 12a to 12n are also dispersedly arranged onto the body of the user, and thus enable the user to calibrate wrong motions by body part. Accordingly, it can be seen that embodiments of the present invention also increase a motion calibration effect for the user.

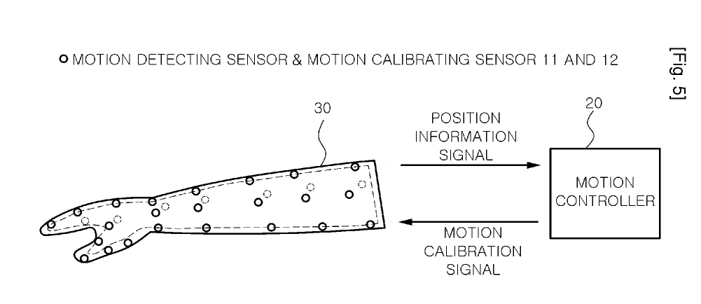

FIG. 5 is an exemplary diagram illustrating another use of the training apparatus based on motion content according to an embodiment of the present invention. In FIG. 5, the motion detecting sensors 11a to 11n and the motion calibrating sensors 12a to 12n are dispersedly arranged onto the worn items of the hands and arms of the user, thereby sensing and controlling the motions of the hands and arms of the user.

As illustrated in FIG. 5, the motion detecting sensors 11a to 11n and the motion calibrating sensors 12a to 12n are dispersedly arranged onto the hands and arms of the user, and particularly joint parts.

Accordingly, the motion detecting sensors 11a to 11n can sense and inform the delicate motions of the hands and arms of the user, and thus the motion controller 20 can more delicately control the body based on the sensed motions.

For example, when the motion of the index finger is different from a motion provided from the motion contents, the motion calibrating sensors 12a to 12n stimulate the feeling of the respective joints of the index finger under the control of the motion controller 20, thereby making the motion of the index finger in accordance with the motion predefined by the motion contents.

While the present invention has been shown and described in connection with the exemplary embodiments, it will be apparent to those skilled in the art that modifications and variations can be made without departing from the spirit and scope of the invention as defined by the appended claims.

1. A training apparatus based on motion content, comprising:
a plurality of motion detecting sensors dispersedly arranged in a body of a user to obtain position information signals of respective body parts of the user;
a motion controller analyzing the position information signals to detect a user motion, and comparing the detected motion with a reference motion provided from motion contents to generate a motion calibration signal for training of a motion calibration; and
a plurality of motion calibrating sensors dispersedly arranged in the body to stimulate the body part of the user according to the motion calibration signal and calibrate the user motion.

2. The training apparatus of claim 1, wherein the motion controller comprises:
a signal interface interfacing a signal transceived between the motion detecting sensors, the motion calibrating sensors and the motion controller;
a current motion analyzer analyzing the position information signal obtained through the motion detecting sensor to detect the user motion;
a motion comparator comparing the user motion with the reference motion provided from the motion contents;
a motion error calculator calculating a motion error which is a difference between the user motion and the reference motion; and
a motion calibration signal generator generating the motion calibration signal for training a motion calibration based on the motion error.

3. The training apparatus of claim 2, wherein the motion controller further comprises a motion content storage storing the motion contents.

4. The training apparatus of claim 2, wherein the motion calibration signal comprises information of a body part where the motion error occurs, an error direction and an error degree.

5. The training apparatus of claim 4, wherein the motion calibrating sensor varies a stimulation direction and stimulation degree of the body part of the user according to the motion calibration signal.

6. A training method based on motion content, comprising:
obtaining a position value by body part of a user to sense a user motion;
comparing a reference motion provided from motion contents with the user motion to calculate a motion error; and
stimulating a feeling of the body part of the user where the motion error occurs to train a motion calibration.

7. The training method of claim 6, wherein the sensing of the user motion comprises:
obtaining the position value by body part of the user through a plurality of motion detecting sensors which are dispersedly arranged in the body of the user; and
analyzing the position value by body part of the user to detect the user motion.

8. The training method of claim 6, wherein the calculating of the motion error comprises comparing the reference motion provided from the motion contents with the user motion to detect a body part where the motion error occurs, an error direction and an error degree.

9. The training method of claim 8, wherein the stimulating of the feeling comprises varying a stimulation direction and stimulation degree of a body part where the motion error occurs through a plurality of motion calibrating sensors which are dispersedly arranged in the body of the user.
